(19) United States
(12) Patent Application Publication
(10) Pub. No.: US 2026/0334145 A1
(43) Pub. Date: Oct. 22, 2026

(54) APPARATUS AND TECHNIQUES FOR GENERATOR CONTROL USING AN INPUT/OUTPUT (IO) HUB

(71) Applicant: Applied Materials, Inc., Santa Clara, CA (US)

(72) Inventors: Byung Dae CHOI, Walnut Creek, CA (US); Jian J. CHEN, Fremont, CA (US); Stephen C. GARNER, Newark, CA (US); Naveen CHANNARAYAPATNA PUTTANNA, BANGALORE (IN)

(21) Appl. No.: 19/309,365

(22) Filed: Aug. 25, 2025

(30) Foreign Application Priority Data
Apr. 17, 2025 (IN) 202541037268

(51) Int. Cl. H01L 21/67; G05B 19/418

(52) U.S. Cl. CPC H10P 72/0618; G05B 19/4186; H10P 72/0604

(57) ABSTRACT

Certain aspects of the present disclosure are directed towards a method for substrate processing. The method generally includes: receiving, via a first interface of a generator hub, a chamber identifier for a chamber associated with an interlock signal; receive, via a second interface, one or more generator identifiers associated with one or more generators; output, via a third interface of a generator hub, the chamber identifier and the one or more generator identifiers to a chamber process device for verification; and receive, via the third interface and from the chamber process device, one or more signals to operate the one or more generators to power the chamber based on the verification.

### CROSS-REFERENCE TO RELATED APPLICATION

This application claims the benefit of and priority to India Provisional Application No. 202541037268 filed Apr. 17, 2025, which is hereby incorporated by reference herein in its entirety as if fully set forth below and for all applicable purposes.

### BACKGROUND

### Field

Aspects of the present disclosure generally relate to a system and methods used in semiconductor device manufacturing. More specifically, aspects of the present disclosure relate to a control system for substrate processing.

### Description of the Related Art

Next generation mainframes for semiconductor processing will grow in size and seek to add a high density of process chambers. Each process chamber may be powered using one or more generators. In some cases, the chambers may be implemented with one or more interlocks that are used to identify whether a chamber has met one or more conditions before power can be provided to the chamber. In some cases, manual jumpers may be used to connect each interlock with associated generators. For example, an interlock selection device may include various jumpers providing connections between specific interlock inputs and generators. Each interlock input may provide a digital signal that indicates whether a particular condition has been met for a respective one of chambers. However, using manual jumper connections for interlock selection may lead to confusion to manufacturing and maintenance personnel and manufacturing issues.

### SUMMARY

Certain aspects are directed towards a method for substrate processing. The method generally includes: receiving, via a first interface of a generator hub, a chamber identifier for a chamber associated with an interlock signal; receiving, via a second interface, one or more generator identifiers associated with one or more generators; outputting, via a third interface of a generator hub, the chamber identifier and the one or more generator identifiers to a chamber process device for verification; and receiving, via the third interface and from the chamber process device, one or more signals to operate the one or more generators to power the chamber based on the verification.

Certain aspects are directed towards a generator hub. The generator hub generally includes: a first interface configured to receive a chamber identifier for a chamber associated with an interlock signal; a second interface configured to receive one or more generator identifiers associated with one or more generators; and a third interface configured to: output the chamber identifier and the one or more generator identifiers to a chamber process device for verification; and receive, from the chamber process device, one or more signals to operate the one or more generators to power the chamber based on the verification.

Certain aspects are directed towards a chamber process device. The chamber process device generally includes: an interface configured to receive a chamber identifier for a chamber associated with an interlock signal, and one or more generator identifiers associated with one or more generators; and a processing device configured to: verify whether the chamber identifier is associated with the one or generator identifiers based on a configured mapping between the chamber and the one or more generators; and output, via the communication interface, one or more signals to operate the one or more generators to power the chamber based on the verification.

### BRIEF DESCRIPTION OF THE DRAWINGS

So that the manner in which the above recited features of the present disclosure can be understood in detail, a more particular description of the disclosure, briefly summarized above, may be had by reference to aspects, some of which are illustrated in the appended drawings. It is to be noted, however, that the appended drawings illustrate only exemplary aspects and are therefore not to be considered limiting of its scope, and may admit to other equally effective aspects.

FIG. 1 illustrates a cross-sectional view of a processing chamber, in which embodiments of the present disclosure may be implemented.

FIG. 2 illustrates a conventional interlock system using manual jumper connections.

FIG. 3 illustrates a generator rack implemented with a generator input/output (I/O) hub, in accordance with certain aspects of the present disclosure.

FIG. 4 illustrates the generator rack including multiple generator I/O hubs for different chambers, in accordance with certain aspects of the present disclosure.

FIG. 5 is a flow diagram illustrating example operations for substrate processing, in accordance with certain aspects of the present disclosure.

To facilitate understanding, identical reference numerals have been used, where possible, to designate identical elements that are common to the figures. It is contemplated that elements and features of one embodiment may be beneficially incorporated in other aspects without further recitation.

### DETAILED DESCRIPTION

Certain aspects of the present disclosure are directed towards a control system used during maintenance activities, idle time, and during substrate processing activities within a substrate processing system. Aspects of the control system are used to monitor and control the movement of hardware and the delivery of fluids, gases, or electrical power to one or more components in a substrate processing system, for example, to ensure that it is safe to move the hardware components and/or deliver the fluids, gases, or electrical power to prevent a user and/or chamber related hardware from being harmed. For example, some aspects provide a generator input/output (I/O) hub that receives chamber and generator identifiers and facilitates verification of whether the correct generator is being used to power the chamber to prevent the user and/or hardware in the process chamber from being damaged. For example, an interlock signal may indicate that a particular chamber has met certain conditions before power is provided to the chamber. In response to the interlock signal, the generator I/O hub may send the identifier of the chamber associated with the interlock and the identifier of the generator to be used by a server that verifies whether the chamber to be powered is correctly mapped to the generator, as described in more detail herein.

### Processing Chamber Example

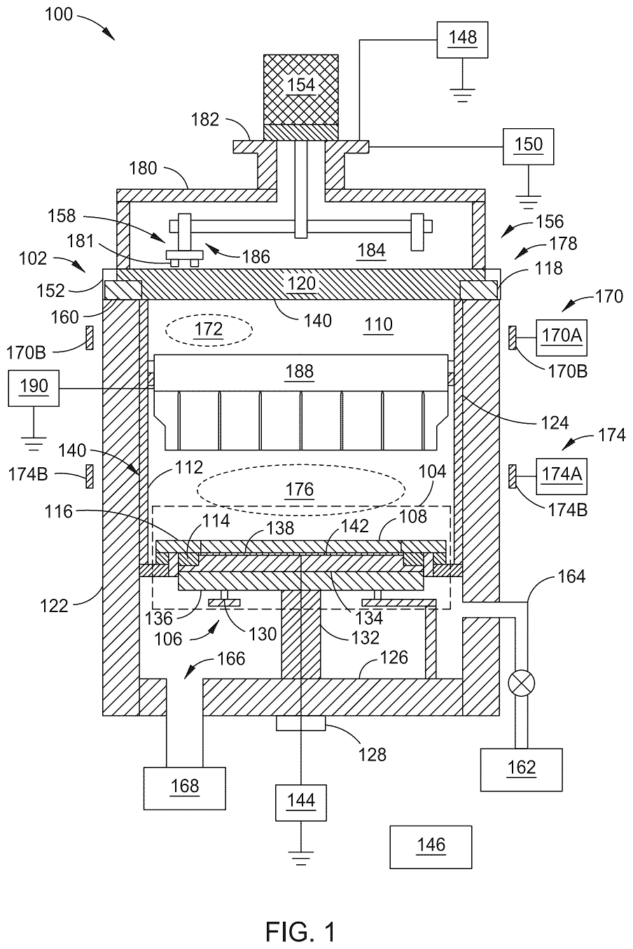

FIG. 1 illustrates a cross-sectional view of a processing chamber 100, in which embodiments of the present disclosure may be implemented. The processing chamber 100 includes an upper process assembly 102, a process kit 104, and a pedestal assembly 106, which are all configured to process a substrate 108 disposed in a processing region 110. The process kit 104 includes a one-piece grounded shield 112, a deposition ring 114, a cover ring 116, and an isolator ring assembly 118. In the version shown, the processing chamber 100 includes a sputtering chamber, also called a physical vapor deposition (PVD) chamber, capable of depositing a single or multi-compositional material from a sputtering target 120 on the substrate 108. The processing chamber 100 may also be used to deposit aluminum (Al), copper (Cu), nickel (Ni), platinum (Pt), hafnium (Hf), silver (Ag), chrome (Cr), gold (Au), molybdenum (Mo), silicon (Si), ruthenium (Ru), tantalum (Ta), tantalum nitride (TaN), tantalum carbide (TaC), titanium nitride (TiN), tungsten (W), tungsten nitride (WN), lanthanum (La), alumina (AlOₓ), lanthanum oxides (LaOₓ), nickel platinum alloys (NiPt), and titanium (Ti), and or a combination thereof.

The processing chamber 100 includes a chamber body 122 having sidewalls 124, a bottom wall 126, and the upper process assembly 102 that enclose the processing region 110 or plasma zone. The chamber body 122 is typically fabricated from welded plates of stainless steel or a unitary block of aluminum. In some embodiments, the sidewalls include aluminum and the bottom portion of the chamber includes one or more walls that are formed from a stainless steel plate. The sidewalls 124 generally contain a slit valve (not shown) to provide for entry and egress of the substrate 108 from the processing chamber 100. Components in the upper process assembly 102 of the processing chamber 100 in cooperation with the grounded shield 112, pedestal assembly 106, and cover ring 116 confine the plasma formed in the processing region 110 to the region above the substrate 108.

The pedestal assembly 106 is supported from the bottom wall 126 of the processing chamber 100. The pedestal assembly 106 supports the deposition ring 114 along with the substrate 108 during processing. The pedestal assembly 106 is coupled to the bottom wall 126 of the processing chamber 100 by a lift mechanism 128, which is configured to move the pedestal assembly 106 between an upper processing position and lower transfer position. Additionally, in the lower transfer position, lift pins 130 are moved through the pedestal assembly 106 to position the substrate 108 a distance from the pedestal assembly 106 to facilitate the exchange of the substrate with a substrate transfer mechanism disposed exterior to the processing chamber 100, such as a single blade robot (not shown). A bellows 132 is typically disposed between the pedestal assembly 106 and the bottom wall 126 to isolate the processing region 110 from the interior of the pedestal assembly 106 and the exterior of the chamber.

The pedestal assembly 106 generally includes a substrate support 134 sealingly coupled to a platform housing 136. The platform housing 136 is typically fabricated from a metallic material such as stainless steel or aluminum. A cooling plate (not shown) is generally disposed within the platform housing 136 enabling thermal regulation of the substrate support 134.

The substrate support 134 may be comprised of aluminum or ceramic. The substrate support 134 has a substrate receiving surface 138 that receives and supports the substrate 108 during processing, the substrate receiving surface 138 being substantially parallel to a sputtering surface 140 of the sputtering target 120. The substrate support 134 may be an electrostatic chuck, a ceramic body, a heater, or a combination thereof. In some embodiments, the substrate support 134 is an electrostatic chuck that includes a dielectric body having an electrode 142, embedded therein. The dielectric body is typically fabricated from a high thermal conductivity dielectric material such as pyrolytic boron nitride, aluminum nitride, silicon nitride, alumina or an equivalent material. Other aspects of the pedestal assembly 106 and substrate support 134 are further described below. In some embodiments, the electrode 142 is configured so that when a DC voltage is applied to the electrode 142, a substrate 108 disposed on the substrate receiving surface 138 will be electrostatically chucked thereto to improve the heat transfer between the substrate 108 and the substrate support 134. In some embodiments, a radio-frequency electromagnetic power delivery system (generator and RF match) or pulsed-voltage (PV) waveform source 144 is electrically coupled to the electrode 142, and is configured to generate a sinusoidal or pulsed-voltage waveform so that a radio-frequency electromagnetic power or pulsed voltage can be provided to the substrate 108 during processing to affect and control the plasma interaction with the surface of the substrate 108.

A program (or computer instructions) readable by a system controller 146 determines which tasks are performable on a substrate. In some embodiments, the system controller 146 includes a computing device having one or more processors, memory, and storage. The one or more processors can include central processing units, graphics processing units, accelerators, etc. The memory includes main memory for storing instructions for the one or more processors to execute or data for the one or more processors to operate on. For example, the memory includes random access memory (RAM). The storage includes mass storage for data or instructions. As an example and not by way of limitation, the storage may include a removable disk drive, flash memory, an optical disc, a magneto-optical disc, magnetic tape, or a Universal Serial Bus drive or two or more of these. The storage may include removable or fixed media and may be internal or external to the computing device. The storage may include any suitable form of non-volatile, solid-state memory, or read-only memory. The system controller 146 includes a non-transitory computer readable medium or media. The non-transitory computer readable medium or media may include one or more semiconductor-based or other integrated circuits (ICs) (such, as for example, field-programmable gate arrays or application-specific ICs), hard disk drives, hybrid hard drives, optical discs, optical disc drives, magneto-optical discs, magneto-optical drives, solid-state drives, RAM drives, any other suitable non-transitory computer readable storage medium/media, or any suitable combination. The non-transitory computer readable medium or media may be volatile, non-volatile, or a combination of volatile and non-volatile.

Preferably, the program is software readable by the system controller 146 that includes code to perform tasks relating to monitoring, execution, and control of the movement and various process recipe tasks and recipe steps being performed in the processing chamber 100. For example, the program can include program code that includes a substrate positioning instruction set to operate the pedestal assembly 106; a gas flow control instruction set to operate gas flow control valves to set a flow of sputtering gas to the processing chamber 100; a gas pressure control instruction set to operate a throttle valve or gate valve to maintain a pressure in the processing chamber 100; a temperature control instruction set to control a temperature control system (not shown) in the pedestal assembly 106 or sidewalls 124 to set temperatures of the substrate 108 or sidewalls 124, respectively; and a process monitoring instruction set to monitor the process in the processing chamber 100.

The upper process assembly 102 may also include an RF source 148, and/or a direct current (DC) source 150, an adaptor 152, a motor 154, and a lid assembly 156. The lid assembly 156 generally includes the sputtering target 120, and a magnetron system 158 that includes a magnetron 186. The upper process assembly 102 is supported by the sidewalls 124 when in a closed position, as shown in FIG. 1. A ceramic target isolator 160 is disposed between the isolator ring assembly 118, the sputtering target 120, and the adaptor 152 of the lid assembly 156 to prevent vacuum leakage there between. The adaptor 152 is sealably coupled to the sidewalls 124, and is configured to help with the removal of the upper process assembly 102 and isolator ring assembly 118.

When in the processing position, the sputtering target 120 is disposed adjacent to the adaptor 152, and is exposed to the processing region 110 of the processing chamber 100. The sputtering target 120 contains material that is deposited on the substrate 108 during a PVD, or sputtering, process. The isolator ring assembly 118 is disposed between the sputtering target 120 and the shield 112. The chamber body 122 may electrically isolate the sputtering target 120 from the shield 112.

During processing, the sputtering target 120 is biased relative to a grounded region of the processing chamber 100 (e.g., the chamber body 122 and the adaptor 152) by a power source disposed in the RF source 148 and/or the DC source 150. It is believed that by delivering RF energy and/or DC power to the sputtering target 120 during a high pressure PVD process, significant process advantages can be achieved over conventional low pressure DC plasma processing techniques when used in conjunction with sputtering materials such as titanium, copper, nickel, ruthenium, aluminum, tantalum, molybdenum, tungsten, and other materials. In some embodiments, the RF source 148 includes an RF power source and an RF match (not shown) that are configured to efficiently deliver RF energy to the sputtering target 120. In some examples, the RF power source is capable of generating RF currents at a frequency of about 13.56 MHz at powers between about 0.1 and about 5 kW. In one or more examples, a DC power supply included in the DC source 150 is capable of delivering between about 0.1 and about 50 kW of DC power.

During processing, a gas, such as argon, is supplied to the processing region 110 from a gas source 162 via conduits 164. The gas source 162 may include an inert gas such as argon, nitrogen, oxygen, krypton, helium or xenon, which is capable of energetically impinging upon and sputtering material from the sputtering target 120 and/or surface of the substrate 108 based on a bias applied which may be applied by the RF energy or PV waveform source 144. The gas source 162 may also include a reactive gas, such as one or more of an oxygen-containing gas or a nitrogen-containing gas, which is capable of reacting with the sputtering material to form a layer on a substrate. Spent process gas and byproducts are exhausted from the processing chamber 100 through exhaust ports 166 that receive spent process gas and direct the spent process gas to an exhaust conduit having an adjustable position gate valve (not shown) to control the pressure in the processing region 110 in the processing chamber 100. The exhaust conduit is connected to one or more exhaust pumps 168, such as a cryopump. Typically, the pressure of the sputtering gas in the processing chamber 100 during processing is set to sub-atmospheric levels, such as a vacuum environment, for example, a pressure of about 0.6 mTorr to about 300 mTorr. In some embodiments, the processing pressure is set to about 20 mTorr to about 100 mTorr.

In some embodiments, a first electromagnet assembly 170 includes a first current source 170A configured to bias a first magnetic coil assembly 170B. The first magnetic coil assembly 170B is positioned near the sputtering target 120, configured to modulate a magnetron-controlled plasma 172. A second electromagnet assembly 174 includes a second current source 174A configured to bias a second magnetic coil assembly 174B. The second magnetic coil assembly 174B is positioned in the central part of the chamber, and configured to modulate a central portion of a plasma 176. The plasma 176 is formed between the substrate 108 and the sputtering target 120 from the gas. Ions within the plasma 176 are accelerated toward the sputtering target 120 and cause material to become dislodged from the sputtering target 120. The dislodged target material is deposited on the substrate 108.

A lid enclosure 178 generally includes a conductive wall 180, a center feed 182, and shielding (not shown). In this configuration, the conductive wall 180, the center feed 182, the sputtering target 120, and a portion of the motor 154 enclose and form a back region 184. The back region 184 is a sealed region disposed on the backside of the sputtering target 120 and is generally filled with a flowing liquid during processing to remove the heat generated at the sputtering target 120 during processing. In some embodiments, the conductive wall 180 and the center feed 182 are configured to support the motor 154 and magnetron system 158, so that the motor 154 can rotate the magnetron system 158 during processing. In one or more embodiments, the motor 154 is electrically isolated from the RF or DC power delivered from the power supplies by use of a dielectric layer, such as Teflon, Delrin, G10, or PEEK. The shielding (not shown) may include one or more dielectric materials that are positioned to enclose and prevent the RF energy delivered to the sputtering target 120 from interfering with and affecting other processing chambers. In some embodiments, the shielding may include a Teflon, Delrin, G10, PEEK or other similar material and/or a thin-grounded sheet metal RF shield.

To provide efficient sputtering, a magnetron system 158 is positioned behind the sputtering target 120 in the upper process assembly 102 to create a magnetic field in the processing region 110 adjacent the sputtering surface 140 of the sputtering target 120, which generates the magnetron-controlled plasma 172. A magnetic field generated by the magnetron system 158 traps electrons and ions to increase the plasma density over one or more regions of the sputtering target 120, and to increase target utilization, control deposition uniformity, and the sputtering rate. In some embodiments, the magnetron system 158 includes a source magnetron assembly consisting of a number of permanent magnet poles 181 bundled tightly together. In some embodiments, a “closed loop” magnetron configuration is formed within the magnetron system 158 such that each magnet pole (not shown) with one polarity (e.g., North or South Pole) of the magnetron is surrounded by the poles (not shown) with opposite polarity forming a continuous loop, resulting in stronger, localized magnetic fields. The magnetron system 158 is rotated about a central axis of the processing chamber 100 by use of the motor 154.

In some embodiments, the magnetron system 158 includes a source magnetron assembly (not shown) that includes an outer pole (not shown) and an inner pole (not shown). In some embodiments, a “closed loop” magnetron configuration is formed within the magnetron system 158 such that the outer pole (not shown) with one polarity of the magnetron surrounds the inner pole (not shown) with opposite polarity of the magnetron forming a gap between the poles that is a continuous loop. In the closed loop configuration, the magnetic fields that emerge and reenter through a surface of the sputtering target form a “closed loop” pattern can be used to confine electrons near the surface of the sputtering target in a closed pattern, which is often called a “racetrack” type pattern. A closed loop, as opposed to the open loop, magnetron configuration is able to confine electrons and generate a high density plasma near the sputtering surface 140 of the sputtering target 120 to increase the sputtering yield. In some other embodiments, an “open loop” magnetron configuration is formed within the magnetron system 158 such that the outer pole of the magnetron surrounds the inner pole of the magnetron forming a gap between the poles that is a continuous loop. In an open loop magnetron configuration, the electrons trapped between the inner and outer poles will migrate, leak out, and escape from the B-fields created at open ends of the magnetron, thus only holding the electrons for a short period of time during the sputtering process due to the reduced confinement of the electrons. It has been found that the use of an open loop magnetron configuration can provide significant step coverage improvements and provide an improved material composition uniformity across the substrate surface, when used in conjunction with the RF and DC sputtering of multi-compositional targets described herein.

In some embodiments, the processing chamber 100 includes a collimator 188 (e.g., a flux optimizer) having a plurality of apertures configured to direct material from the sputtering target 120 though the collimator 188 and towards the substrate 108 in a manner that can control/adjust a number of ions arriving and an angle of arrival of the ions onto portions of the substrate 108. In one or more embodiments, a DC voltage source 190 is electrically coupled to the collimator 188 and configured to apply a positive DC bias to the collimator 188 relative to ground. The positive DC bias is configured to attract sputtered metal ions formed in the magnetron-controlled plasma 172. In some examples, the positive DC bias is configured to alter a plasma potential relative to ground of the plasma 176 formed in the processing region 110 of the processing chamber 100. In some embodiments, the positive DC bias is a voltage in a range of 0.1 V to 300 V. In other embodiments, the positive DC bias may be greater than 300 V.

In various embodiments, altering the plasma potential relative to ground may cause the plasma potential of the plasma 176 to be up to 200 V greater than the positive DC bias applied to the collimator 188 relative to ground. If the PV waveform source 144 delivers the PV waveform to the electrode 142 having pulses with amplitudes that extend from ground or a first negative voltage relative to ground to a second negative voltage relative to ground, then it is not possible to cause ions to have energy levels below a threshold energy level. For example, it is not possible to generate ion energies in a range from ground to the plasma potential of the plasma 176. However, ions having ion energies in the range from ground to the plasma potential are necessary for various low energy, directional deposition processes and/or processes involving materials with a relatively low relative permittivity.

In order to generate ion energies in the range from ground to the plasma potential of the plasma 176, the one or more processors of the system controller 146 execute instructions that cause the one or more processors to reconfigure the amplitudes of the pulses in the PV waveform. In some examples, the one or more processors adjust the amplitudes to extend from a positive voltage relative ground to a negative voltage relative to ground. The positive voltage relative to ground may further raise the plasma potential relative to ground. In other examples, the one or more processors adjust the amplitudes to extend from a first positive voltage relative to ground to a second positive voltage relative to ground. The first positive voltage relative to ground may further raise the plasma potential relative to ground. The second positive voltage relative to ground may modulate the plasma potential relative to ground.

### Example Techniques for Generator Control

Certain aspects of the present disclosure are directed towards a generator input/output (I/O) hub facilitating remote control of power generators by linking the generators to unique binary-coded identifiers. These identifiers enable a chamber process server (e.g., or any controller or device) to gather information facilitating the verification of power generators and associated interlock connections. In this manner, the safe use, precise monitoring, and increased reliability of generator controls may be obtained.

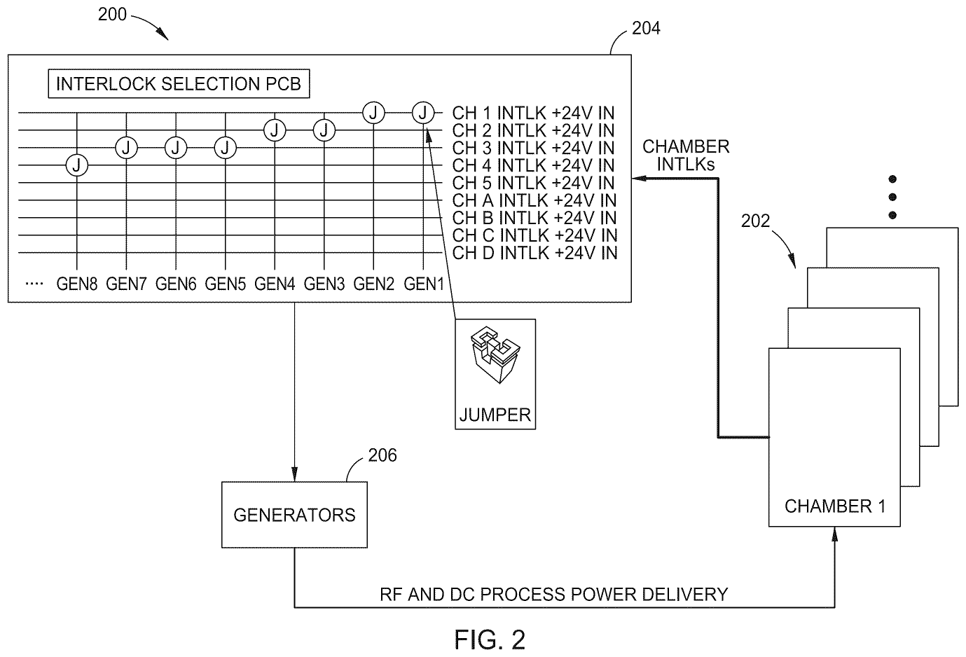

FIG. 2 illustrates a conventional interlock system 200 using manual jumper connections that are used to configure the interconnection of interlocks associated with components within a chamber to assure the safe delivery of electrical power to one or more components within a process chamber. An interlock selection device 204 (e.g., printed circuit board (PCB)) may include various jumpers providing connections between specific interlock inputs and generators. Each interlock input may provide a digital signal that indicates whether a particular condition has been met for a respective one of chambers 202. For example, an interlock signal may be received from a sensor of the chamber indicating whether a chamber lid is closed before power (e.g., radio frequency (RF) power and/or direct current (DC) power) can be provided for that chamber using a generator. As shown, depending on the location of each jumper (e.g., labeled “J”), the interlock signal may be routed to enable the ability to turn on a generator to be used to provide power to that chamber. However, using manual jumper connections for interlock selection may lead to confusion to manufacturing and maintenance personnel and manufacturing issues. For example, a jumper may be misplaced, resulting in the wrong generator being enabled.

In an effort to avoid these types of unsafe conditions, certain aspects of the design disclosed herein provide a generator I/O hub with digital identifiers that clearly specify interlock origins and generator types. This enhancement improves diagnostics, simplifies troubleshooting, and reduces downtime. Certain aspects also use an Ethernet for control automation technology (EtherCAT) connection (e.g., an Ethernet interface) to enhance communication performance, although any suitable communication technology may be used.

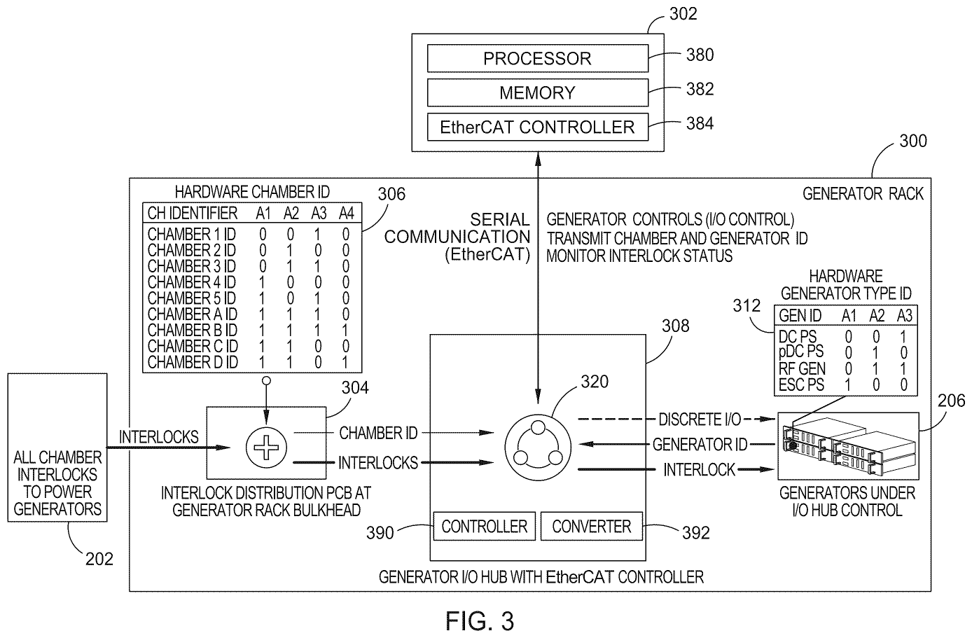

FIG. 3 illustrates a generator rack 300 implemented with a generator I/O hub 308, in accordance with certain aspects of the present disclosure. As shown, the rack 300 may include an interlock distribution device 304 (e.g., PCB), which may be located at the generator rack bulkhead. The interlock distribution device 304 may receive interlock signals from chambers 202 and combine each interlock signal with an associated chamber identifier (ID) shown in table 306. Table 306 shows various hardware chamber IDs. Each chamber, such as chambers 1-5 and A-D, may be associated with a unique ID that may include four bits that are supplied in a communication signal and/or stored in memory in the example provided. For instance, chamber 1 may be associated ID 0010b, chamber 2 may be associated ID 0100, and so on.

Each interlock input (e.g., port) of the interlock distribution device 304 may correspond to a specific chamber. The mapping between each chamber and a corresponding interlock input of the interlock distribution device 304 is configured at the interlock distribution device 304, allowing the interlock distribution device 304 to identify when a particular chamber has been plugged in via a cable for interlock communication. Thus, depending on the interlock input at which a particular interlock signal is received, the interlock distribution device 304 identifies the associated ID for the chamber and combines the chamber ID with the interlock signal to be provided to the hub 308.

The interlock and associated chamber ID may be provided to the generator I/O hub 308, which may be implemented with one or more interfaces 320 to facilitate communications with other devices such as a chamber process server 302. For example, the I/O hub 308 may include an EtherCAT controller used to control sending and receiving information to a chamber process server 302. While an EtherCAT connection is used in the examples provided, any suitable communication technology may be used.

As shown, each of the generators 206 may also be associated with an identifier, as listed in table 312. A chamber may be associated with one or more generators, such as a DC power supply (PS) associated with ID 001b, a pulsed DC (pDC) PS associated with ID 010b, an RF generator (RF GEN) associated with ID 011b, and electrostatic chuck (ESC) PS associated with ID 100b. In some implementations, each generator (e.g., power supply) may be plugged into the hub 308 using a respective cable and port (interface), allowing the hub 308 to identify when a particular generator has been plugged in. The hub 308 may receive the generator ID(s) for a particular chamber from the associated generator(s) along with the interlock signal and chamber ID from the distribution device 304. The interlock signal, the associated chamber ID, and the generator ID(s) may be sent to the chamber process server 302 via an EtherCAT controller 390 and an EtherCAT interface.

During the initial setup of the generator rack, the chamber process server 302 may be configured with the mapping between each chamber ID and the associated generator(s). Using the mapping, the chamber process server 302 may verify (e.g., using a processing device 380 coupled to memory 382) the mapping between the chamber ID for the interlock signal and the associated generator ID(s) (e.g., to ensure that the correct generator(s) are being operated for the interlock). In other words, the chamber process server 302 may confirm that generator(s) associated with the received generator ID(s) are correctly mapped to the chamber associated with the chamber ID. For example, suppose the wrong generator is plugged into a particular generator port of the hub 308. In that case, the wrong generator ID may be received by the hub 308 and forwarded to the chamber process server 302. Based on known mappings between generators and chambers, the server 302 may then identify that the generator is not associated with the chamber and not allow the generator to be operated. In some aspects, the server 302 may output a user notification indicating the identified issue.

If verification is successful, the chamber process server 302 may communicate with the hub 308 using an EtherCAT controller 384 and via the EtherCAT interface to set up the associated generator(s) and enable the generator(s) once setup is complete. A discrete I/O interface may provide one or more analog signals to set up each generator. For example, the discrete I/O interface may be used to set up how much power the generator generates, receive a power reading indicating how much power is being provided to a chamber, or other readings such as voltage level or current reading. The discrete I/O interface enables forward and reflected power output readings, as well as for transmitting set points of power generators. The hub 308 may receive, via the EtherCAT connection (interface), setup parameters for each generator. The hub 308 may include a converter 392 (e.g., digital-to-analog converter (DAC)) that generates the analog signal to be provided to the generator to set up the generator as requested by the chamber process server 302. Once set up is complete, the chamber process server 302 may again control the hub 308 to provide the interlock signal that enables the associated generator(s).

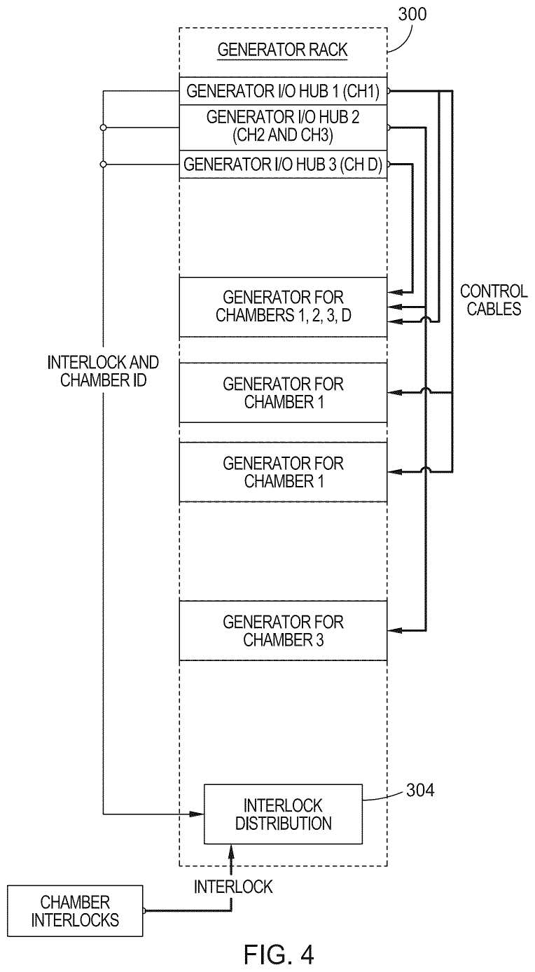

FIG. 4 illustrates the generator rack 300 including multiple generator I/O hubs for different chambers, in accordance with certain aspects of the present disclosure. As shown, the generator rack 300 may include multiple generator I/O hubs labeled “Generator I/O Hub 1,” “Generator I/O Hub 2,” and “Generator I/O Hub 3.” Generator I/O Hub1 may be for a first chamber (CH1), Generator I/O Hub 2 may be for a second chamber (CH2) and a third chamber (CH3), and Generator I/O Hub 3 may be for a third chamber (CH3). The rack 300 may also include generators; each generator may be designated to provide power to one or more chambers. As shown, each hub may be coupled to generators designated to associated chambers. For example, Generator I/O Hub 1 may be coupled to generators for chamber 1 using respective control cables. Generator I/O Hub 1 may receive an interlock signal and an associated chamber ID for CH1 from the interlock distribution device 304, as described herein. The Generator I/O Hub 1 may also receive generator IDs from the generators for CH1. Using an EtherCAT controller, the Generator I/O Hub 1 may send the generator IDs and chamber ID to the server (e.g., server 302 of FIG. 3) for verification before setting up and enabling the generators to power CH1.

Certain aspects are directed toward managing power generators through a high-performance EtherCAT communication protocol that enables precise remote control and real-time data acquisition. Some aspects provide interfaces for monitoring forward and reflected power outputs and transmitting set points of power generators. Certain aspects also provide an integrated interlock logic circuit to ensure operations occur in a safe sequence and prevent unintended high-power supply operations. The modular connectivity of the generator I/O hub improves the remote control of power generators within a designated chamber. A group of power generators may be linked to a corresponding chamber interlock, identified by a unique binary code, referred to herein as a chamber identifier. As described, the unique chamber and generator identifiers may be captured and transmitted to the chamber process server for verification. The server may verify that the group of power generators is correctly linked with a designated chamber, facilitating accurate monitoring and control of the power generators within the chamber. In some aspects, the number of power generators connected to the generator I/O hub may be monitored, triggering the chamber process server to verify and monitor the connection status in real time.

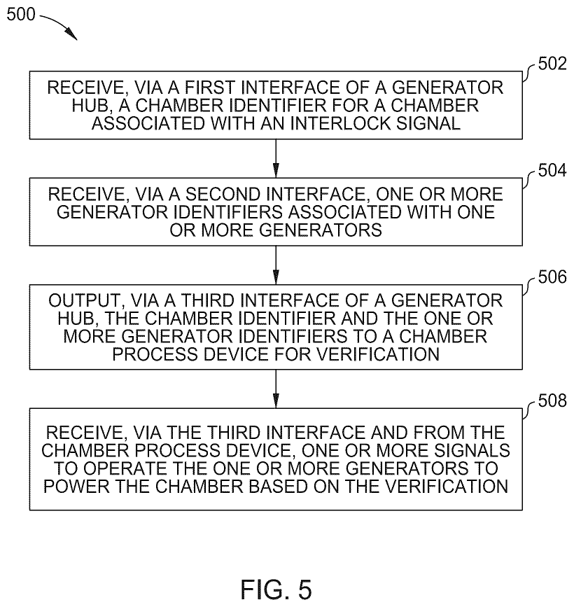

FIG. 5 is a flow diagram illustrating example operations 500 for substrate processing, in accordance with certain aspects of the present disclosure. The operations 500 may be performed via a control system, such as a control system including the generator I/O hub 308, the interlock distribution device 304, and/or a chamber process device (e.g., server 302).

At block 502, the control system may receive, via at least one first interface of a generator hub (e.g., generator hub 308), a chamber identifier for a chamber associated with an interlock signal. The chamber identifier may be received the chamber identifier from an interlock distribution device (e.g., interlock distribution device 304).

At block 504, the control system may receive, via the at least one first interface, one or more generator identifiers associated with one or more generators. The one or more generator identifiers may be received from the one or more generators.

At block 506, the control system may output, via a second interface of a generator hub, the chamber identifier and the one or more generator identifiers to a chamber process device for verification. In some aspects, the chamber identifier and the one or more generator identifiers are output to the chamber process device via an Ethernet cable. The chamber identifier and the one or more generator identifiers may be output to the chamber process device using an Ethernet for control automation technology (EtherCAT) controller (e.g., controller 390) of the generator hub.

At block 508, the control system may receive, via the second interface and from the chamber process device, one or more signals to operate the one or more generators to power the chamber based on the verification.

In some aspects, the control system may generate, via a converter (e.g., converter 392) of the generator hub, one or more analog control signals based on the one or more signals from the chamber process device. The control system may output, via the second interface, the one or more analog control signals to operate the one or more generators. The one or more analog control signals may include: at least one first signal for setting one or more operating parameters of the one or more generators.

In some aspects, the control system receives receiving the interlock signal via an interlock distribution device (e.g., interlock distribution device 304) and determines, via the interlock distribution device, the chamber identifier associated with the interlock signal. The control system may provide, via the interlock distribution device, the chamber identifier to the generator hub.

In some aspects, the chamber is one of a plurality of chambers. The interlock distribution device may include multiple input ports, the interlock signal being received via one of the multiple input ports. The chamber identifier may be determined based on a mapping between the one of the multiple input ports and the chamber associated with the chamber identifier.

In some aspects, the control system may verify, via the chamber process device, whether the chamber identifier is associated with the one or generator identifiers based on a configured mapping between the chamber and the one or more generators. The control system may output, via the chamber process device, the one or more signals to operate the one or more generator to power the chamber based on the verification. As described, if the one or more generator identifiers are not mapped to the chamber identifier, the chamber process device does not allow the one or more generators to be used for powering the chamber. The interlock signal may indicate whether the chamber has met one or more conditions before operating the one or more generators to power the chamber.

Certain aspects of the present disclosure provide a control system with reduced cost, increased scalability, and reduced maintenance while providing diagnostic capabilities and redundancy. The control system described herein may be easily expandable or modified by adding/removing elements (e.g., hubs and generators) without major redesigns. Each element (e.g., generator/hub) of the control system can be quickly replaced, reducing downtime for maintenance. The server may provide clear indicators for quick issue identification and resolution. For example, the server may indicate when a mapping between an interlock signal for a chamber and a generator is incorrect. The control system enhances reliability with duplicated functions, providing continuous operation. Instead of relying only on experts to correctly set up and operate chambers and generators, the server performs an added verification step, increasing reliability.

While the foregoing is directed to aspects of the present disclosure, other and further aspects of the disclosure may be devised without departing from the basic scope thereof, and the scope thereof is determined by the claims that follow.

What is claimed is:

1. A method for substrate processing, comprising:
receiving, via a first interface of a generator hub, a chamber identifier for a chamber associated with an interlock signal;
receiving, via a second interface, one or more generator identifiers associated with one or more generators;
outputting, via a third interface of a generator hub, the chamber identifier and the one or more generator identifiers to a chamber process device for verification; and
receiving, via the third interface and from the chamber process device, one or more signals to operate the one or more generators to power the chamber based on the verification.

2. The method of claim 1, wherein the chamber identifier and the one or more generator identifiers are output to the chamber process device via an Ethernet cable.

3. The method of claim 1, wherein the chamber identifier and the one or more generator identifiers are output to the chamber process device using an Ethernet for control automation technology (EtherCAT) controller of the generator hub.

4. The method of claim 1, further comprising:
generating, via a converter of the generator hub, one or more analog control signals based on the one or more signals from the chamber process device; and
outputting, via the second interface, the one or more analog control signals to operate the one or more generators.

5. The method of claim 4, wherein the one or more analog control signals set one or more operating parameters of the one or more generators.

6. The method of claim 1, further comprising:
receiving the interlock signal via an interlock distribution device;
determining, via the interlock distribution device, the chamber identifier associated with the interlock signal; and
providing, via the interlock distribution device, the chamber identifier to the generator hub.

7. The method of claim 6, wherein:
the chamber is one of a plurality of chambers;
the interlock distribution device comprises multiple input ports, the interlock signal being received via one of the multiple input ports; and
the chamber identifier is determined based on a mapping between the one of the multiple input ports and the chamber associated with the chamber identifier.

8. The method claim 1, further comprising:
verifying, via the chamber process device, whether the chamber identifier is associated with the one or generator identifiers based on a configured mapping between the chamber and the one or more generators; and
outputting, via the chamber process device, the one or more signals to operate the one or more generator to power the chamber based on the verification.

9. The method of claim 1, wherein the interlock signal indicates whether the chamber has met one or more conditions before operating the one or more generators to power the chamber.

10. A generator hub comprising:
a first interface configured to receive a chamber identifier for a chamber associated with an interlock signal;
a second interface configured to receive one or more generator identifiers associated with one or more generators; and
a third interface configured to:
output the chamber identifier and the one or more generator identifiers to a chamber process device for verification; and
receive, from the chamber process device, one or more signals to operate the one or more generators to power the chamber based on the verification.

11. The generator hub of claim 10, wherein the third interface comprises an Ethernet interface configured to output the chamber identifier and the one or more generator identifiers via an Ethernet cable.

12. The generator hub of claim 10, further comprising an Ethernet for control automation technology (EtherCAT) controller configured to output the chamber identifier and the one or more generator identifiers via the third interface.

13. The generator hub of claim 10, further comprising a converter configured to generate one or more analog control signals based on the one or more signals from the chamber process device, wherein the second interface is configured to output the one or more analog control signals to operate the one or more generators.

14. The generator hub of claim 13, wherein the one or more analog control signals are configured to set one or more operating parameters of the one or more generators.

15. A control system including the generator hub of claim 10, further comprising an interlock distribution device configured to:
receive the interlock signal;
determine the chamber identifier associated with the interlock signal; and
provide the chamber identifier to the generator hub.

16. The control system of claim 15, wherein:
the chamber is one of a plurality of chambers;
the interlock distribution device comprises multiple input ports, one of the multiple input ports being configured to receive the interlock signal; and
the interlock distribution device is configured to determine the chamber identifier based on a mapping between the one of the multiple input ports and the chamber associated with the chamber identifier.

17. A control system including the generator hub of claim 10, the control system further comprising the chamber process device configured to:
verify whether the chamber identifier is associated with the one or generator identifiers based on a configured mapping between the chamber and the one or more generators; and
output the one or more signals to operate the one or more generator to power the chamber based on the verification.

18. The generator hub of claim 10, wherein the interlock signal is configured to indicate whether the chamber has met one or more conditions before operating the one or more generators to power the chamber.

19. A chamber process device, comprising:
an interface configured to receive a chamber identifier for a chamber associated with an interlock signal, and one or more generator identifiers associated with one or more generators; and
a processing device configured to:
verify whether the chamber identifier is associated with the one or generator identifiers based on a configured mapping between the chamber and the one or more generators; and
output, via the interface, one or more signals to operate the one or more generators to power the chamber based on the verification.

20. The chamber process device of claim 19, wherein the interface comprises an Ethernet interface configured to receive the chamber identifier and the one or more generator identifiers via an Ethernet cable.
